(19) United States
(12) Patent Application Publication
(10) Pub. No.: US 2023/0232578 A1
(43) Pub. Date: Jul. 20, 2023

(54) SCREW-TYPE PUMPING DEVICE AND LIQUID-COOLED HEAT DISSIPATION DEVICE

(71) Applicant: Dongguan city think-cool thermal dissipation technologies Co., Ltd., Dongguan City (CN)

(72) Inventors: Xiao FAN, Dongguan City (CN); Haohui TANG, Dongguan City (CN); Haoqiang DENG, Dongguan City (CN)

(21) Appl. No.: 17/651,051

(22) Filed: Feb. 14, 2022

(30) Foreign Application Priority Data
Jan. 20, 2022 (CN) 202220157098.1

(51) Int. Cl. H05K 7/20; F04D 29/42; F04D 13/06

(52) U.S. Cl. CPC H05K 7/20272; F04D 29/426; F04D 13/0606; H05K 7/20263

(57) ABSTRACT

The screw-type pumping device includes a water pump shell, a stator and a rotor. The water pump shell is provided with a first cavity for accommodating the stator and a second cavity for accommodating the rotor. At one end close to the second cavity, the water pump shell is provided with an outwardly-extending water pump water chamber, the water pump water chamber is internally provided with a screw configured to rotate coaxially with the rotor, and the water pump water chamber is provided with a first water port and a second water port which are in communication with the water pump water chamber. An objective of the present invention is to provide a screw-type pumping device and a liquid-cooled heat dissipation device. The newly designed screw-type pumping device can output higher hydraulic pressure while having a smaller vibration during high-speed rotation and a prolonged service life.

### TECHNICAL FIELD

The present invention relates to the technical field of liquid-cooled heat dissipation, and in particular to a screw-type pumping device and a liquid-cooled heat dissipation device.

### BACKGROUND

At present, heat dissipation apparatuses for cooling down computer CPUs, video cards, electronic instrument chips and other apparatuses usually take the form of a water-cooled heat sink, which basically consists of three parts, namely, a heat absorption device, a pumping device and a heat dissipation device, which are connected to form a closed liquid circulation loop. The heat absorption device is connected to a heat generating element, and the pumping device is used to provide power for liquid to circulate in the loop. The three parts are assembled and fixed by means of external connection pipes, therefore, this design has the disadvantages of occupying a relatively large space, being inconvenient for installation and operation, having high requirements for installation space, and having poor installation flexibility, so its application is greatly limited.

In order to meet the increasingly stringent requirements of space requirements, small-sized pumping devices are available in the related art, which use the traditional impeller centrifugal method to extract liquid, but the amount of liquid pumped by such pumping devices depends on the diameter of the impeller. Therefore, such pumping devices have a limited hydraulic pressure in a limited transverse space, and cannot be applied to environments with higher hydraulic pressure requirements. In addition, if the diameter of the impeller is too large, it will cause more vibration during rotation, affecting the service life of the pumping device.

### SUMMARY

In order to overcome the shortcomings and deficiencies in the related art, the present invention aims to provide a screw-type pumping device and a liquid-cooled heat dissipation device. The newly designed screw-type pumping device can output higher hydraulic pressure while having a smaller vibration during high-speed rotation and a prolonged service life.

The present invention is achieved by the following technical scheme:

a screw-type pumping device, including a water pump shell, a stator and a rotor. The water pump shell is provided with a first cavity for accommodating the stator and a second cavity for accommodating the rotor. At one end close to the second cavity, the water pump shell is provided with an outwardly-extending water pump water chamber, the water pump water chamber is internally provided with a screw configured to rotate coaxially with the rotor, and the water pump water chamber is provided with a first water port and a second water port which are in communication with the water pump water chamber.

Further, the screw-type pumping device further includes a water pump base. The water pump base is provided with a mounting hole, and the water pump shell is mounted in the mounting hole.

Further, the water pump base is provided with a third water port in communication with the first water port.

Further, the screw-type pumping device further includes a shaft body, two ends of the shaft body are respectively connected to the second cavity and the water pump water chamber, and the rotor and the screw are both rotatably connected to the shaft body.

Further, the rotor and the screw are integrally formed.

Further, there are a plurality of second water ports, and the plurality of second water ports are arranged in an array at a bottom end of the water pump water chamber.

The present invention further discloses a liquid-cooled heat dissipation device, including a first water chamber, a first interface in communication with the first water chamber, and the screw-type pumping device as described above. The first interface is mounted on one side of the first water chamber. The pumping device is provided in an embedded manner in the first water chamber, the first water port is in communication with the first interface, and the second water port is in communication with the first water chamber.

Further, the first water chamber is internally provided with a partition plate for partitioning the interior of the first water chamber, the first water chamber is partitioned by the partition plate to form a second water chamber and a third water chamber, and the screw-type pumping device is provided in an embedded manner in the second water chamber.

Further, the heat dissipation device further includes a fourth water chamber, a plurality of cooling tubes and a plurality of heat dissipation structure devices, where the plurality of heat dissipation structure devices are arranged at intervals, and each cooling tube is arranged between adjacent heat dissipation structure devices. The plurality of cooling tubes have one end in communication with the fourth water chamber, some of the cooling tubes have the other end in communication with the second water chamber, and the remaining cooling tubes have the other end in communication with the third water chamber.

Further, the heat dissipation structure devices are heat dissipation fins or heat dissipation wavy plates.

The present invention has the following beneficial effects:

1. Smaller size requirements: compared with the existing centrifugal pumps, the screw-type pumping device of the present invention has an elongated structure and can be better accommodated in an elongated space.

2. Smaller vibration during high-speed rotation: compared with the existing designs of the impeller of the centrifugal pump, the diameter of the screw is much smaller than that of the impeller, and the vibration during high-speed rotation of the present invention is smaller, so that a higher rotation speed can be realized to achieve the purpose of outputting higher hydraulic pressure.

### BRIEF DESCRIPTION OF DRAWINGS

The present invention will be further illustrated with reference to the accompanying drawings, but the embodiments in the accompanying drawings do not constitute any limitation to the present invention. For those of ordinary skill in the art, other drawings can be obtained according to the following drawings without involving any creative efforts.

FIG. 1 is a schematic structural view of a screw-type pumping device of the present invention.

FIG. 2 is a schematic structural view of a liquid-cooled heat dissipation device of the present invention.

FIG. 3 is a schematic exploded structural view of the liquid-cooled heat dissipation device of the present invention.

FIG. 4 is a sectional view of the liquid-cooled heat dissipation device of the present invention.

### LIST OF REFERENCE NUMERALS

Pumping device—100; Water pump shell—101; Stator—102; Rotor—103; First cavity—104; Second cavity—105; Water pump water chamber—106; Screw—107; First water port—108; Second water port—109; Water pump base—110; Mounting hole—111; Third water port—112; Shaft body—113; Fastener—115; Water pump cover—116;

First water chamber—201; First interface—202; Partition plate—203; Second water chamber—204; Third water chamber—205; Fourth water chamber—206; Cooling tube—207; Heat dissipation structure device—208; First opening—209; Second interface—210.

### DETAILED DESCRIPTION

In order to make the above-mentioned objective, features and advantages of the present invention more obvious and easier to understand, the specific embodiments of the present invention will be described in detail below with reference to the accompanying drawings. In the following description, numerous specific details are set forth to facilitate full understanding of the present invention. However, the present invention can be implemented in many other ways different from those described herein, and those skilled in the art can make similar improvements without violating the connotation of the present invention, so the present invention is not limited by the specific embodiments disclosed below.

In the description of the present invention, it should be understood that, descriptions relating to orientation, for example, orientation or positional relationships indicated by “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise” “counterclockwise” “axial”, “radial”, “circumferential”, etc. are based on the orientation or positional relationships shown in the accompanying drawings, and are to facilitate the description of the present invention and simplify the description only, rather than indicate or imply that the device or element mentioned must have a specific orientation or be constructed and operated in a specific orientation, and therefore cannot be construed as limiting the present invention.

In addition, the terms “first” and “second” are for the purpose of description only and should not be construed as indicating or implying relative importance or implicitly indicating the number of technical features indicated. Therefore, the features defined with “first” and “second” may explicitly or implicitly include at least one of the features. In the description of the present invention, the term “a plurality of” means at least two, for example, two or three or more, unless otherwise explicitly and specifically defined.

### EXAMPLE 1

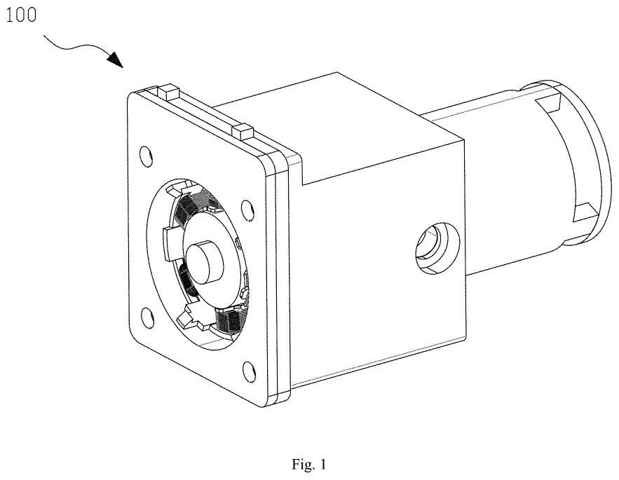

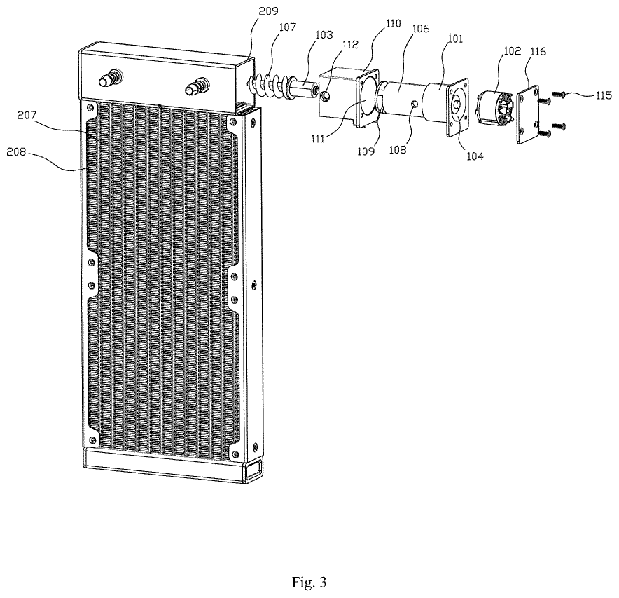

As shown in FIGS. 1, 3 and 4, an embodiment of the present invention discloses a screw-type pumping device, including a water pump shell 101, a stator 102 and a rotor 103. The water pump shell 101 is provided with a first cavity 104 for accommodating the stator 102 and a second cavity 105 for accommodating the rotor 103. At one end close to the second cavity 105, the water pump shell 101 is provided with an outwardly-extending water pump water chamber 106, the water pump water chamber 106 is internally provided with a screw 107 configured to rotate coaxially with the rotor 103, and the water pump water chamber 106 is provided with a first water port 108 and a second water port 109 which are in communication with the water pump water chamber 106.

In actual use, the stator 102 is electrified to drive the rotor 103 to rotate, and the rotation of the rotor 103 drives the screw 107 to rotate. The rotor 103 and the screw 107 are integrally formed. The pumping device of this embodiment further includes a shaft body 113. Two ends of the shaft body 113 are respectively connected to the second cavity 105 and the water pump water chamber 106. The rotor 103 and the screw 107 are both rotatably connected to the shaft body 113, and bearings are respectively mounted between the rotor 103 and the shaft body 113 and between the screw 107 and the shaft body to increase the rotation accuracy of the rotor 103 and the screw 107. In addition, the first water port 108 is a water outlet and the second water port 109 is a water inlet. Since the pumping device 100 of this embodiment can output higher water pressure, there are provided a plurality of second water ports 109, and the plurality of second water ports 109 are arranged in an array at a bottom end of the water pump water chamber 106. After liquid enters the water pump water chamber 106 from the second water port 109, the liquid rises spirally along the screw 107 and is discharged through the first water port 108.

Specifically, the pumping device 100 of this embodiment further includes a water pump base 110. The water pump base 110 is provided with a mounting hole 111, the water pump shell 101 mounted in the mounting hole 111, and a third water port 112 in communication with the first water port 108 is provided at a corresponding position of the water pump base 110. By providing the water pump base 110, the pumping device 100 of this embodiment can be stably mounted.

### EXAMPLE 2

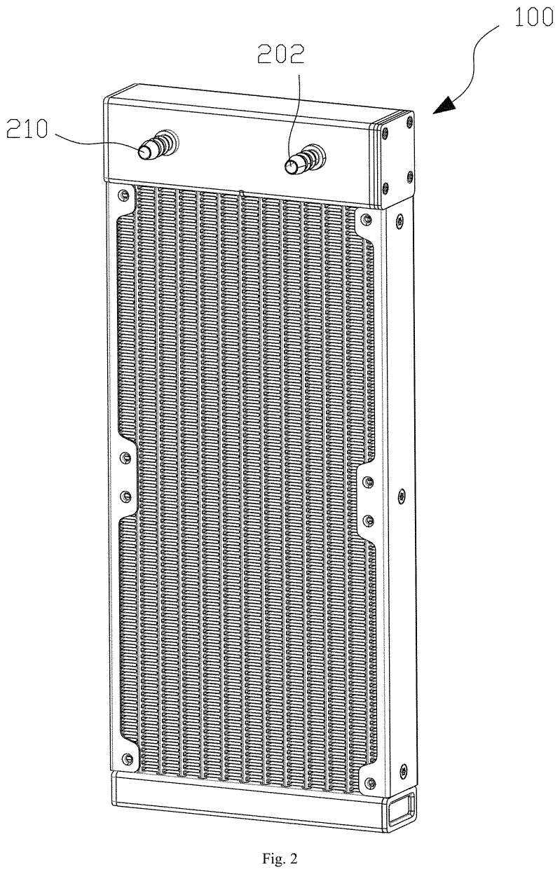

As shown in FIGS. 1-4, an embodiment of the present invention discloses a liquid-cooled heat dissipation device, including a first water chamber 201, a first interface 202 in communication with the first water chamber 201, and the screw-type pumping device as described above. The first interface 202 is mounted on one side of the first water chamber 201. The pumping device 100 is provided in an embedded manner in the first water chamber 201, the first water port 108 is in communication with the first interface 202, and the second water port 109 is in communication with the first water chamber 201. In this embodiment, a fastener 115 passes through a water pump cover 116, the water pump shell 101 and the water pump base 110 in sequence for fixing. A main board (not shown) controls the magnetic field intensity of the stator 102 to control the rotation speed of the rotor 103, and the rotation of the screw 107 generates power for the liquid to flow through the water pump water chamber 106, so as to drive the liquid to circulate in the heat dissipation device. Since the space in the first water chamber 201 is relatively elongated, the pumping device 100 of this embodiment can be better accommodated in this space.

Specifically, the heat dissipation device of this embodiment further includes a fourth water chamber 206, a plurality of cooling tubes 207 and a plurality of heat dissipation structure devices 208. The plurality of heat dissipation structure devices 208 are arranged at intervals, and each cooling tube 207 is arranged between adjacent heat dissipation structure devices 208. Preferably, the heat dissipation structure devices 208 are heat dissipation fins or heat dissipation wavy plates. Each of the plurality of cooling tubes 207 has one end in communication with a fourth water chamber 206, some of the cooling tubes 207 have the other end in communication with the second water chamber 204, and the remaining cooling tubes 207 have the other end in communication with the third water chamber 205. The first water chamber 201 is partitioned by a partition plate 203 into a second water chamber 204 and a third water chamber 205. One side of the third water chamber 205 is provided with a second interface 210 communicating therewith, and the first interface 202 is then communication with the second water chamber 204. That is, except for the structure of the first water chamber 201, the other structures of the heat dissipation device of this embodiment are the same as those of the related art, and their working principles will not be described in detail.

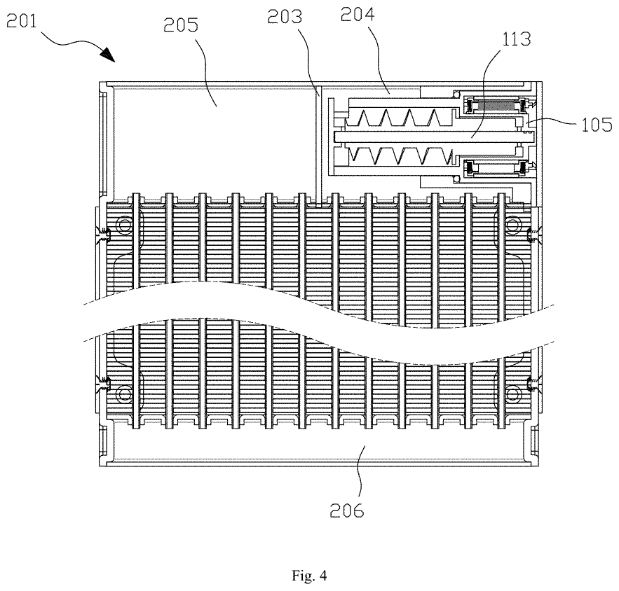

As shown in FIGS. 4 and 5, specifically, the first water chamber 201 is provided with a first opening 209, and the pumping device 100 is provided in an embedded manner in the first opening 209. Specifically, the water pump base 110 is provided in an embedded manner in the first opening 209.

To sum up, the screw-type pumping device and the liquid-cooled heat dissipation device of the present invention have the following beneficial effects:

1. Smaller size requirements: compared with the existing centrifugal pumps, the screw-type pumping device of the present invention has an elongated structure and can be better accommodated in an elongated space.

2. Smaller vibration during high-speed rotation: compared with the existing designs of the impeller of the centrifugal pump, the diameter of the screw 107 is much smaller than that of the impeller, and the vibration during high-speed rotation of the present invention is smaller, so that a higher rotation speed can be realized to achieve the purpose of outputting higher hydraulic pressure.

3. The output water pressure of the screw 107 is higher. If it is necessary for the heat dissipation device to absorb heat from multiple heat sources or the flow channel is too long, the flow attenuation of the present invention is smaller than that of other forms of pumps.

4. The design of the pumping device 100 has less eddy current in the water pump water chamber 106 because one end of the pumping device is for water intake and the other end is for water discharge.

Finally, it should be noted that the above embodiments are only used to illustrate the technical scheme of the present invention, and not to limit the scope of protection of the present invention. Although the present invention has been described in detail with reference to the preferred embodiments, those of ordinary skill in the art should understand that modifications and equivalent substitutions can be made to the technical scheme of the present invention without departing from the essence and scope of the technical scheme of the present invention.

What is claimed is:

1. A screw-type pumping device, comprising a water pump shell (101), a stator (102) and a rotor (103), the water pump shell (101) being provided with a first cavity (104) for accommodating the stator (102) and a second cavity (105) for accommodating the rotor (103), wherein at one end close to the second cavity (105), the water pump shell (101) is provided with an outwardly-extending water pump water chamber (106), the water pump water chamber (106) is internally provided with a screw (107) configured to rotate coaxially with the rotor (103), and the water pump water chamber (106) is provided with a first water port (108) and a second water port (109) which are in communication with the water pump water chamber (106).

2. The screw-type pumping device of claim 1, further comprising a water pump base (110), wherein the water pump base (110) is provided with a mounting hole (111), and the water pump shell (101) is mounted in the mounting hole (111).

3. The screw-type pumping device of claim 2, wherein the water pump base (110) is provided with a third water port (112) in communication with the first water port (108).

4. The screw-type pumping device of claim 1, further comprising a shaft body (113), wherein two ends of the shaft body (113) are respectively connected to the second cavity (105) and the water pump water chamber (106), and the rotor (103) and the screw (107) are both rotatably connected to the shaft body (113).

5. The screw-type pumping device of claim 1, wherein the rotor (103) and the screw (107) are integrally formed.

6. The screw-type pumping device of claim 1, wherein there are a plurality of second water ports (109), and the plurality of second water ports (109) are arranged in an array at a bottom end of the water pump water chamber (106).

7. A liquid-cooled heat dissipation device, comprising a first water chamber (201) and a first interface (202) in communication with the first water chamber (201), the first interface (202) being mounted on one side of the first water chamber (201), wherein the liquid-cooled heat dissipation device further comprises the screw-type pumping device of claim 1, the pumping device (100) is provided in an embedded manner in the first water chamber (201), the first water port (108) is in communication with the first interface (202), and the second water port (109) is in communication with the first water chamber (201).

8. The liquid-cooled heat dissipation device of claim 7, wherein the first water chamber (201) is internally provided with a partition plate (203) for partitioning the interior of the first water chamber (201), the first water chamber (201) is partitioned by the partition plate (203) to form a second water chamber (204) and a third water chamber (205), and the screw-type pumping device is provided in an embedded manner in the second water chamber (204).

9. The liquid-cooled heat dissipation device of claim 8, further comprising a fourth water chamber (206), a plurality of cooling tubes (207) and a plurality of heat dissipation structure devices (208), wherein the plurality of heat dissipation structure devices (208) are arranged at intervals, and each cooling tube (207) is arranged between adjacent heat dissipation structure devices (208); and the plurality of cooling tubes (207) have one end in communication with the fourth water chamber (206), some of the cooling tubes (207) have the other end in communication with the second water chamber (204), and the remaining cooling tubes (207) have the other end in communication with the third water chamber (205).

10. The liquid-cooled heat dissipation device of claim 9, wherein the heat dissipation structure devices (208) are heat dissipation fins or heat dissipation wavy plates.
